(19) United States
(12) Patent Application Publication
(10) Pub. No.: US 2025/0147409 A1
(43) Pub. Date: May 8, 2025

(54) METHOD FOR MANUFACTURING SEMICONDUCTOR DEVICE

(71) Applicant: SAMSUNG ELECTRONICS CO., LTD., SUWON-SI (KR)

(72) Inventors: Woo-Yong JUNG, Suwon-si (KR); Joon Hyun KIM, Suwon-si (KR); Seung Yoon LEE, Suwon-si (KR); Jeong Jin LEE, Suwon-si (KR); Chan HWANG, Suwon-si (KR)

(21) Appl. No.: 18/773,908

(22) Filed: Jul. 16, 2024

(30) Foreign Application Priority Data
Nov. 2, 2023 (KR) 10-2023-0149654

(51) Int. Cl. G03F 1/42

(52) U.S. Cl. CPC G03F 1/42

(57) ABSTRACT

A method for manufacturing a semiconductor device includes providing a first pre-reticle including a first overlay mark and a first on-cell pattern. A second pre-reticle is provided that includes a second overlay mark and a second on-cell pattern. A first pattern is formed from the first pre-reticle using a first illumination system. A second pattern is formed from the second pre-reticle using a second illumination system. An overlay error is measured between the first pattern and the second pattern. A corrected reticle is formed based on the measured overlay error.

### CROSS-REFERENCE TO RELATED APPLICATION

This application claims priority under 35 U.S.C. § 119 to Korean Patent Application No. 10-2023-0149654, filed on Nov. 2, 2023 in the Korean Intellectual Property Office, the disclosure of which is incorporated by reference in its entirety herein.

### 1. TECHNICAL FIELD

The present disclosure relates to a method for manufacturing a semiconductor device. More specifically, the present disclosure relates to a method for manufacturing a semiconductor device using overlay metrology.

### 2. DISCUSSION OF RELATED ART

The integration level of semiconductor devices has increased along with the advancement of the information society. As the integration level of semiconductor devices increases, a line width of a pattern included in the semiconductor device generally becomes finer. As complex processes and materials are applied thereto, the difficulty of a measurement process is also increasing.

An overlay measurement process is a process that determines an alignment state between a lower pattern and an upper pattern, such as an overlay, on a substrate. To precisely determine the overlay, an overlay mark may be applied to each pattern. However, distortion may occur during the overlay measurement process due to the introduction of a new material or a complex manufacturing process. As a result, the difficulty of the overlay measurement is increasing.

### SUMMARY

A technical purpose to be achieved by embodiments of the present disclosure is to provide a method for manufacturing a semiconductor device using an overlay measurement process with increased reliability.

Another technical purpose to be achieved by embodiments of the present disclosure is to provide a method for manufacturing a semiconductor device using a more simplified overlay measurement process.

Purposes in accordance with embodiments of the present disclosure are not limited to the above-mentioned purpose. Other purposes and advantages in accordance with the present disclosure as not mentioned above may be understood from following descriptions and more clearly understood from embodiments in accordance with the present disclosure. Further, it will be readily appreciated that the purposes and advantages in accordance with embodiments of the present disclosure may be realized by features and combinations thereof as disclosed in the claims.

According to an embodiment of the present disclosure, a method for manufacturing a semiconductor device includes providing a first pre-reticle including a first overlay mark and a first on-cell pattern. A second pre-reticle is provided that includes a second overlay mark and a second on-cell pattern. A first pattern is formed from the first pre-reticle using a first illumination system. A second pattern is formed from the second pre-reticle using a second illumination system. An overlay error is measured between the first pattern and the second pattern. A corrected reticle is formed based on the measured overlay error.

According to an embodiment of the present disclosure, a method for manufacturing a semiconductor device includes providing a pre-reticle including an overlay mark and an on-cell pattern. An overlay measurement stack is formed from the pre-reticle. The overlay measurement stack includes a lower pattern and an upper pattern. An overlay error is measured between the lower pattern and the upper pattern. A corrected reticle is formed based on the measured overlay error. The forming of the overlay measurement stack includes forming the lower pattern from a first pre-reticle using a first illumination system. The upper pattern is formed on top of the lower pattern from a second pre-reticle using a second illumination system.

According to an embodiment of the present disclosure, a method for manufacturing a semiconductor device includes providing a first pre-reticle including first overlay marks. A second pre-reticle is provided that includes second overlay marks. An overlay measurement wafer is formed from the first and second pre-reticles. The overlay measurement wafer includes a lower pattern and an upper pattern. An overlay error is measured between the lower pattern and the upper pattern. A corrected reticle is formed based on the measured overlay error. The forming of the overlay measurement wafer includes: forming the lower pattern from the first pre-reticle using a first illumination system of a first cell pattern. A light-transmissive film is formed on the lower pattern. An upper pattern is formed on the light-transmissive film from the second pre-reticle using a second illumination system of a second cell pattern.

Specific details of some embodiments of the present disclosure are included in the detailed descriptions and drawings.

### BRIEF DESCRIPTION OF DRAWINGS

The above and other aspects and features of the present disclosure will become more apparent by describing in detail non-limiting embodiments thereof with reference to the attached drawings, in which:

FIG. 1 is a block diagram illustrating an overlay measurement device used in a method for manufacturing a semiconductor device according to an embodiment of the present disclosure.

FIG. 2 is a schematic diagram illustrating a spectroscopic image measurement device used in a method for manufacturing a semiconductor device according to an embodiment of the present disclosure.

FIG. 3 is a diagram for illustrating a method for manufacturing a semiconductor device according to an embodiment of the present disclosure, and is a top view showing a top surface of a wafer.

FIG. 4 and FIG. 5 are diagrams showing overlay measurement according to some embodiments of the present disclosure and are diagrams for illustrating an overlay measurement reticle.

FIG. 6 is a diagram showing overlay measurement according to an embodiment, and is a diagram for illustrating an overlay measurement stack.

FIG. 7 and FIG. 8 are diagrams showing overlay measurement according to some embodiments of the present disclosure, and are diagrams for illustrating an illumination system that is used to form the overlay measurement stack.

FIG. 9 is a diagram for illustrating overlay values measured according to an embodiment of the present disclosure, and is a diagram corresponding to a shot area SA in FIG. 3.

FIG. 10 and FIG. 11 are diagrams for illustrating a result of correcting a calculated average overlay value according to some embodiments of the present disclosure.

FIG. 12 and FIG. 13 are diagrams for illustrating an effect of a method for manufacturing a semiconductor device according to some embodiments of the present disclosure.

FIG. 14 is a flowchart for illustrating a method for manufacturing a semiconductor device according to an embodiment of the present disclosure.

### DETAILED DESCRIPTIONS OF EMBODIMENTS

For simplicity and clarity of illustration, elements in the drawings may not be drawn to scale. The same reference numbers in different drawings represent the same or similar elements, and as such may perform similar functionality. Further, descriptions and details of well-known steps and elements may be omitted for simplicity of the description. Furthermore, in the following detailed description of embodiments of the present disclosure, numerous specific details are set forth to provide a thorough understanding of the present disclosure. However, it will be understood that the present disclosure may be practiced without these specific details. In other instances, well-known methods, procedures, components, and circuits have not been described in detail so as not to unnecessarily obscure aspects of embodiments of the present disclosure. Examples of various embodiments are illustrated and described further below. It will be understood that the description herein is not intended to limit the claims to the specific embodiments described. On the contrary, it is intended to cover alternatives, modifications, and equivalents as may be included in the spirit and scope of the present disclosure.

Embodiments of the present disclosure are not necessarily limited to a shape, a size, a ratio, an angle, a number, etc. disclosed in the drawings for illustrating embodiments of the present disclosure. The same reference numerals refer to the same elements herein.

The terminology used herein is for the purpose of describing particular embodiments only and is not intended to limit embodiments of the present disclosure. As used herein, the singular forms “a” and “an” are intended to include the plural forms as well, unless the context clearly indicates otherwise. It will be further understood that the terms “comprises”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify the entirety of list of elements and may not modify the individual elements of the list. When referring to “C to D”, this means C inclusive to D inclusive unless otherwise specified.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of embodiments of the present disclosure.

In addition, it will also be understood that when a first element or layer is referred to as being present “on” or “beneath” a second element or layer, the first element may be disposed directly on or beneath the second element or may be disposed indirectly on or beneath the second element with a third element or layer being disposed between the first and second elements or layers. It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not interposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

Unless otherwise defined, all terms including technical and scientific terms used herein have the same meaning as commonly understood by one of ordinary skill in the art to which embodiments of the present disclosure belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In one example, when a certain embodiment may be implemented differently, a function or operation specified in a specific block may occur in a sequence different from that specified in a flowchart. For example, two consecutive blocks may actually be executed at the same time. Depending on a related function or operation, the blocks may be executed in a reverse sequence.

In descriptions of temporal relationships, for example, temporal precedent relationships between two events such as “after”, “subsequent to”, “before”, etc., another event may occur therebetween unless “directly after”, “directly subsequent” or “directly before” is not indicated.

The features of the various embodiments of the present disclosure may be partially or entirely combined with each other, and may be technically associated with each other or operate with each other. The described embodiments may be implemented independently of each other and may be implemented together in an association relationship.

Spatially relative terms, such as “beneath,” “below,” “lower,” “under,” “above,” “upper,” and the like, may be used herein for ease of explanation to describe the relationship of one element or feature to another element or feature as illustrated in the figures. It will be understood that the spatially relative terms are intended to encompass different orientations of the device in use or in operation, in addition to the orientation depicted in the figures. For example, when the device in the drawings is turned over, elements described as “below” or “beneath” or “under” other elements or features would then be oriented “above” the other elements or features. Thus, the example terms “below” and “under” may encompass both an orientation of above and below. The device may be otherwise oriented for example, rotated 90 degrees or at other orientations, and the spatially relative descriptors used herein should be interpreted accordingly.

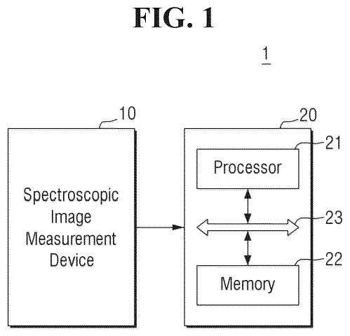

Hereinafter, with reference to FIGS. 1 to 14, a method for manufacturing a semiconductor device according to some embodiments will be described.

FIG. 1 is a block diagram illustrating an overlay measurement device used in a method for manufacturing a semiconductor device according to some embodiments.

Referring to FIG. 1, an overlay measurement device 1 according to some embodiments includes a spectroscopic image measurement device 10 and a computing system 20.

In an embodiment, the spectroscopic image measurement device 10 may irradiate measuring light to a target substrate (e.g., a semiconductor wafer) and measure characteristic values of the target substrate based on reflected light reflected from the target substrate. For example, in an embodiment the spectroscopic image measurement device 10 may analyze the target substrate based on a result of detecting a polarization state and diffraction of the light reflected from the target substrate. Accordingly, in an embodiment the spectroscopic image measurement device 10 may provide various information about the target substrate, including a complex refractive index, a shape, a crystal state, a chemical structure, and electrical conductivity, as well as a thickness of each of a thin film and the target substrate. Thus, the spectroscopic image measurement device 10 may detect an alignment between a lower layer and an upper layer.

In an embodiment, the computing system 20 may receive data measured by the spectroscopic image measurement device 10, such as the data regarding the polarization state of the light reflected from the target substrate. The computing system 20 may then analyze the received data.

In some embodiments, the computing system 20 may include a processor 21 and memory 22. In an embodiment, the processor 21 and the memory 22 may exchange data with each other via a bus 23. For example, the data measured by the spectroscopic image measurement device 10 may be transmitted to the computing system 20 and then stored in the memory 22 of the computing system 20. Additionally, the data stored in the memory 22 may be displayed as a graph or may be subjected to various analysis processes via analysis software or applications which are executed on the processor 21.

In an embodiment, the memory 22 may store, therein, as one output file, recipe information as setting information for measuring the overlay, such as an arrangement and a size of a measurement target area and a center wavelength, a bandwidth, and a spectrum structure of measuring light, and a periodic ratio, a contrast, or Kernel 3-sigma indicating an overlay error between the lower layer and the upper layer.

In an embodiment, the computing system 20 may include, but is not necessarily limited to, portable computers such as desktop computers, servers, notebook computers, and laptop computers, as well as mobile computers including smartphones and tablet computers. In one example, the computing system 20 may be directly connected (e.g., via a cable) to the spectroscopic image measurement device 10, or may be connected thereto via a wired network including a LAN (Local Area Network), a WAN (WideArea Network), or via a wireless network including a WiFi network, or a cellular network such that the computing system 20 and the spectroscopic image measurement device 10 may exchange the data with each other.

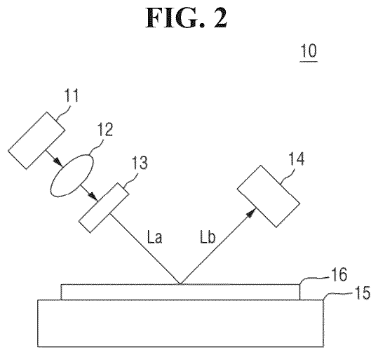

FIG. 2 is an example schematic diagram illustrating a spectroscopic image measurement device used in a method for manufacturing a semiconductor device according to an embodiment.

Referring to FIG. 2, in an embodiment the spectroscopic image measurement device 10 according to an embodiment may include a light source 11, a spectrometer 12, a filter 13, an image sensor 14, and a stage 15. In an embodiment, the spectroscopic image measurement device 10 may use mixed light including a continuous wavelength band as the measuring light La. However, embodiments of the present disclosure are not necessarily limited thereto. According to an embodiment, the spectroscopic image measurement device 10 may use light of a short wavelength as the measuring light La.

In some embodiments, the light source 11 may be a white light source. However, embodiments of the present disclosure are not necessarily limited thereto. The spectrometer 12 and the filter 13 may be used to convert the light emitted from the light source 11 into light having a specific wavelength or light having a wavelength in a specific band.

In an embodiment, the spectrometer 12 may spread the light emitted from the light source 11 according to a wavelength and provide the spread light to the filter 13. In an embodiment, the filter 13 may receive the spread light and may generate the measuring light La that is to be irradiated to a wafer 16. In an embodiment, the filter 13 may control the central wavelength of the measuring light La and a wavelength band of the measuring light La, and may determine the spectral structure (e.g., a single pass band or a double pass band) of the wavelength of the measuring light La.

In an embodiment, the light generated from the filter 13 may be polarized by a polarizer and then the polarized light may be irradiated to the target substrate, for example, the wafer 16 located on the stage 15 at a predetermined angle of incidence through an illumination optical system. In some embodiments, the light generated from the filter 13 may be irradiated to the wafer 16 through a compensator as well as the polarizer, or may be irradiated to the wafer 16 through a phase modulator instead of the compensator.

In an embodiment, the image sensor 14 may receive reflected light Lb reflected from the wafer 16, and may measure polarization change, diffraction, energy size change, etc. into an image. In an embodiment, the image sensor 14 may detect the overlay error between the lower layer and the upper layer based on the measurement result. The data collected in a form of the image may be transmitted to the computing system 200 in FIG. 1 which may process the data.

In this way, the spectroscopic image measurement device 10 may perform measurement on the wafer 16. In an embodiment, the wafer 16 may be subjected to exposure in an exposure device and then may be moved onto the stage 15. However, embodiments of the present disclosure are not necessarily limited thereto. For example, in an embodiment the wafer 16 may be subjected to etching in an etching device and then may be transferred onto the stage 15.

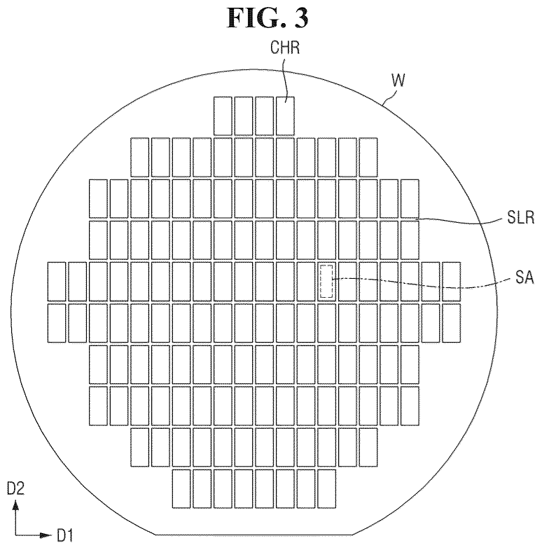

Hereinafter, a method for manufacturing a semiconductor device according to some embodiments will be described using FIGS. 3 to 11 and FIG. 14.

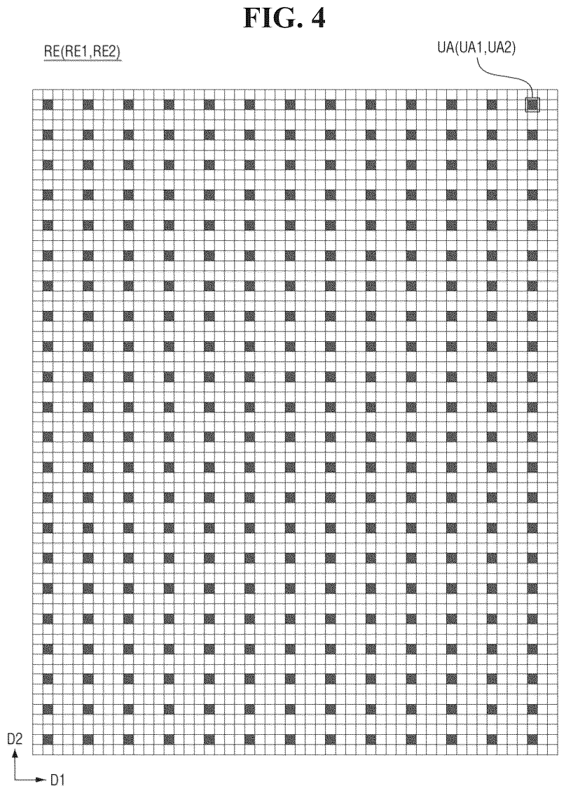

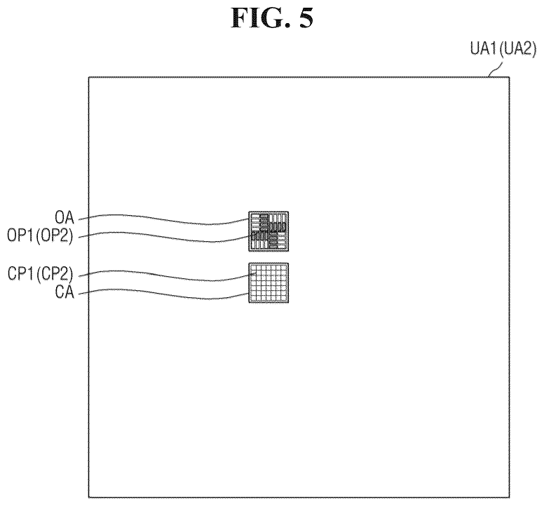

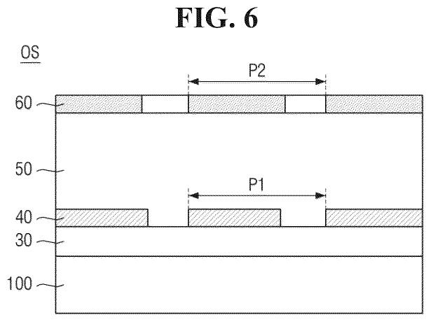

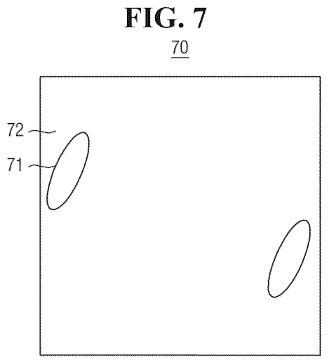

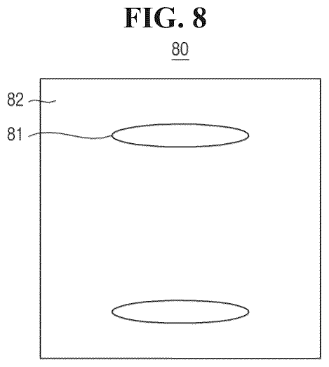

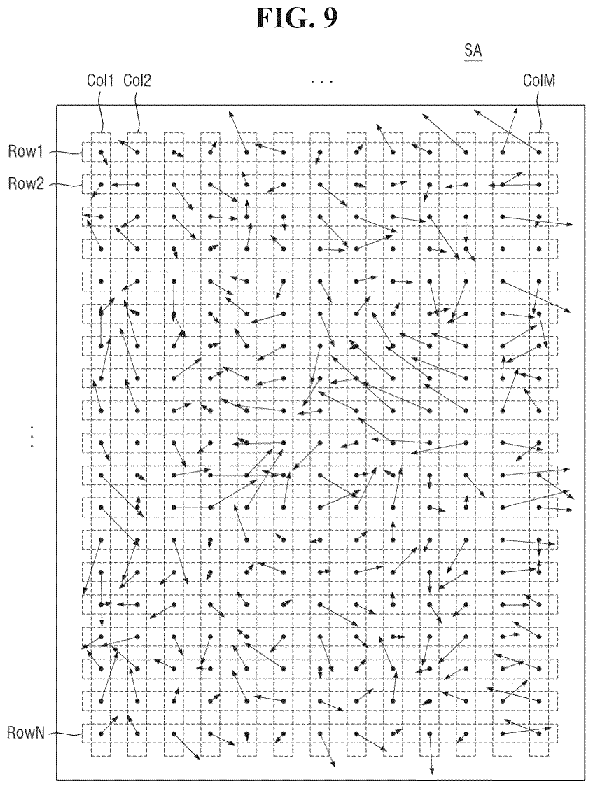

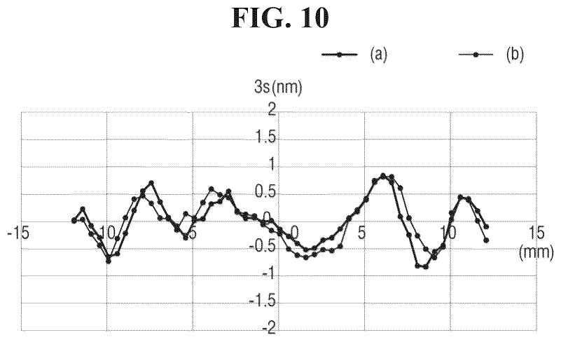

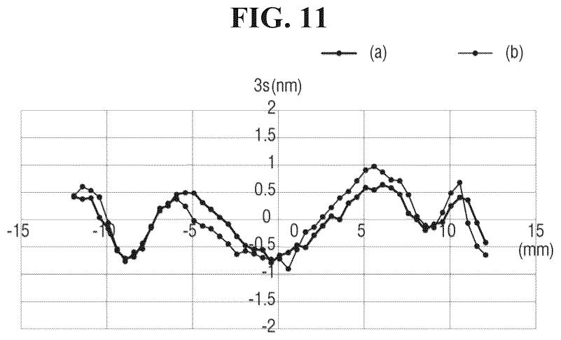

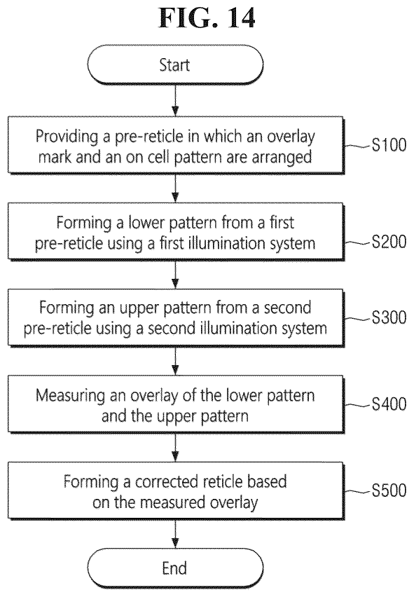

FIG. 3 is a diagram for illustrating a method for manufacturing a semiconductor device according to an embodiment, and is a top view showing a top surface of a wafer. FIG. 4 and FIG. 5 are diagrams showing measuring an overlay according to some embodiments and are diagrams for illustrating a pre-reticle. FIG. 6 is a diagram showing overlay measurement according to an embodiment and is a diagram for illustrating an overlay measurement stack. FIG. 7 and FIG. 8 are diagrams showing overlay measurement according to some embodiments, and are diagrams for illustrating an illumination system that is used to form the overlay measurement stack. FIG. 9 is a diagram for illustrating overlay values measured according to an embodiment, and is a diagram corresponding to a shot area SA in FIG. 3. FIG. 10 and FIG. 11 are diagrams for illustrating a result of correcting a calculated average overlay value according to some embodiments. FIG. 14 is a flowchart for illustrating a method for manufacturing a semiconductor device according to an embodiment.

Referring to FIG. 3, in an embodiment a wafer W may include a plurality of chip areas CHR and a scribe line area SLR crossing between the chip areas CHR (e.g., in the first and second directions DR1, DR2).

The chip areas CHR may be disposed on an upper surface of the wafer W and may be arranged along a first direction D1 and a second direction D2 that intersects perpendicularly to the first direction D1. Each chip area CHR may be surrounded with the scribe line area SLR. However, embodiments of the present disclosure are not necessarily limited thereto and the first and second directions DR1, DR2 may intersect each other at various different angles.

In an embodiment, semiconductor memory elements such as dynamic random access memory (DRAM), static random access memory (SRAM), NAND flash memory, and resistive random access memory (RRAM) may be provided on the chip areas CHR. Alternatively, a processor such as a micro electro-mechanical systems (MEMS) element, an optoelectronic element, a CPU, or a DSP may be provided on the chip areas CHR. Alternatively, standard cells including semiconductor elements such as OR gates or AND gates may be provided on the chip areas CHR. Redistribution chip pads for inputting and outputting data or signals to semiconductor integrated circuits and redistribution pads for inputting and outputting signals to test circuits may be connected to each of the chip areas CHR.

In an embodiment, the scribe line area SLR may extend in the first direction D1 and the second direction D2 and between the chip areas CHR. In an embodiment, the scribe line area SLR may include a cutting area that will be cut by a sawing or cutting machine during the manufacturing process and edge areas between the cutting area and the chip areas CHR.

The wafer W may include a plurality of shot areas SA. In an embodiment, each shot area SA may have a rectangular shape (e.g., in a plan view defined in the first and second directions DR1, DR2). However, embodiments of the present disclosure are not necessarily limited thereto. In an embodiment, the shot area SA may be an entire area of a lithography mask that may be transferred to the wafer W (or photoresist formed on the wafer) via a one time exposure. A circuit pattern formed in different masks may transferred, in an overlapping manner, to the shot area SA to form a semiconductor device.

In some embodiments, the shot area SA may have a size of about 26 mm in the first direction D1 and a size of about 33 mm in the second direction D2. However, embodiments of the present disclosure are not necessarily limited thereto. One shot area SA may include chip areas CHR of various numbers and sizes depending on a type and specifications of an element to be formed. For example, in an embodiment the shot area SA may include only one chip area.

Referring to FIG. 4, FIG. 5, and FIG. 14, an overlay measurement reticle RE in which overlay marks OP1 and OP2 and on-cell patterns CP1 and CP2 are arranged may be provided in block S100 (FIG. 14). In some embodiments, the overlay measurement reticle RE may be referred to as the pre-reticle. Furthermore, measuring the overlay may mean detecting (e.g., measuring) the overlay error. Furthermore, the on-cell patterns CP1 and CP2 may refer to patterns having substantially the same pitch as that of actual cell patterns formed after an exposure process and an etching process have been performed.

In an embodiment, the overlay measurement reticle RE may include a plurality of overlay marks OP1 and OP2 and a plurality of on-cell patterns CP and CP2 arranged in the shot area SA.

In some embodiments, a pitch of the overlay marks OP1 and OP2 may be greater than a pitch of the on-cell patterns CP1 and CP2. However, embodiments of the present disclosure are not necessarily limited thereto.

In an embodiment, the overlay measurement reticle RE may include a first pre-reticle RE1 and a second pre-reticle RE2. The first pre-reticle RE1 and the second pre-reticle RE2 may be respectively positioned at different first and second levels, respectively. For example, in an embodiment the first pre-reticle RE1 may be positioned at a first level as a lower level, and the second pre-reticle RE2 may be positioned at a second level as a higher level than the first level. In an embodiment, the first pre-reticle RE1 and the second pre-reticle RE2 may overlap each other in a vertical direction which may cross the first and second directions DR1, DR2.

The overlay measurement reticle RE may include a plurality of unit areas UA. For example, in an embodiment the plurality of unit areas UA may be arranged at high density. For example, in an embodiment 52 unit areas may be arranged along the first direction D1 and 66 unit areas may be arranged along the second direction D2.

The first pre-reticle RE1 may include a first unit area UA1, and the second pre-reticle RE2 may include a second unit area UA2. The first unit area UA1 and the second unit area UA2 may be respectively positioned at the different first and second levels from each other. For example, in an embodiment the first unit area UA1 may be positioned at the first level as the lower level, and the second unit area UA2 may be positioned at the second level as the higher level than the first level. In an embodiment, the first unit area UA1 and the second unit area UA2 may overlap each other in the vertical direction.

The first unit area UA1 may include the first overlay mark OP1 in an overlay area OA and the first on-cell pattern CP1 in a cell area CA. The second unit area UA2 may include the second overlay mark OP2 in the overlay area OA and the second on-cell pattern CP2 in the cell area CA. The arrangement and the number of the overlay marks OP1 and OP2 and the arrangement and the number of the on-cell patterns CP and CP2 are illustrative and embodiments of the present disclosure are not necessarily limited to those shown in FIG. 5.

Referring to FIG. 6, the overlay measurement stack OS may be formed using the overlay measurement reticle RE. In an embodiment, the overlay measurement stack OS may include a substrate 100, a lower film 30, a lower pattern 40, an upper film 50, and an upper pattern 60, as described later. In some embodiments, the overlay measurement stack OS may be referred to as an overlay measurement wafer.

Referring to FIG. 6 to FIG. 8, the lower pattern 40 (e.g., a first pattern) may be formed from the first pre-reticle RE1 using a first illumination system 70. Subsequently, the upper pattern 60 (e.g., a second pattern) may be formed from the second pre-reticle RE2 using a second illumination system 80.

In an embodiment, in forming the lower pattern 40 and the upper pattern 60, the illumination systems 70 and 80 having different light-transmissive areas 71 and 81 may be used, respectively. For example, to form the lower pattern 40, the first illumination system 70 with the first light-transmissive area 71 in a first light-blocking area 72 may be used. To form the upper pattern 60, the second illumination system 80 having the second light-transmissive area 81 in a second light-blocking area 82 may be used. For example, the first and second light-blocking areas 72, 82 may surround the first and second light-transmissive areas 71, 81, respectively (e.g., in the first and second directions DR1, DR2).

In an embodiment, a process of optimizing (e.g., adjusting) a condition of each of the illumination systems 70 and 80 so that the light rays correspond to the light-transmissive areas 71 and 81 to increase the accuracy and efficiency of forming the respective patterns 40 and 60 may be performed.

For example, in an embodiment each of the illumination systems 70 and 80 may include a beam shaper for converting the light rays generated from the light source into light rays corresponding to each of the light-transmissive areas 71 and 81.

In an embodiment, each of the illumination systems 70 and 80 may be applied to an actual cell pattern. For example, the first illumination system 70 may be an illumination system applied to a first actual cell pattern, and the second illumination system 80 may be an illumination system applied to a second actual cell pattern.

In an embodiment, a laser light source or EUV light source may be used as the light source.

For example, in an embodiment the laser light source with a central wavelength in a range of about 150 nm to 500 nm may be used as the light source. For example, an excimer laser light source such as a G-line laser, I-line laser, KrF laser, ArF laser, or F₂ laser may be used as the light source. However, embodiments of the present disclosure are not necessarily limited thereto.

Alternatively, for example, in an embodiment a light source with a central wavelength in a range of about 4 nm to 120 nm, such as a light source with a central wavelength in a range of about 4 nm to about 20 nm may be used as the light source. In an embodiment, an extreme ultraviolet (EUV) light source with a central wavelength of about 13.5 nm may be used as the light source.

For example, in an embodiment the first illumination system may employ the laser light source, and the second illumination system may employ the EUV light source. However, embodiments of the present disclosure are not necessarily limited thereto. For example, in an embodiment, the second illumination system may employ the laser light source, and the first illumination system may employ the EUV light source.

Referring to FIG. 6, FIG. 7, and FIG. 14, the lower pattern 40 may be formed from the first pre-reticle RE1 using the first illumination system 70 in block S200 (FIG. 14). In an embodiment, the lower pattern 40 may be formed by performing a first exposure process using the first illumination system 70.

In an embodiment, the substrate 100 may first be provided. In an embodiment, the lower pattern 40 may be formed on (e.g., formed directly thereon) the substrate 100. In an embodiment, the substrate 100 may be made of bulk silicon or SOI (silicon-on-insulator). The substrate 100 may be a silicon substrate, or may include a material other than silicon, such as silicon germanium, gallium arsenide, silicon germanium on insulator (SGOI), indium antimonide, lead telluride compound, indium arsenide, indium phosphide, gallium arsenide, or gallium antimonide. Alternatively, the substrate 100 may include a base substrate and an epitaxial layer formed on the base substrate, or may be a ceramic substrate, a quartz substrate, or a glass substrate for display. However, embodiments of the present disclosure are not necessarily limited thereto.

In an embodiment, the substrate 100 may include a cell area and an overlay area. Unit cell patterns (e.g., a lower cell pattern and an upper cell pattern) for implementing a semiconductor device (e.g., a semiconductor memory device) may be formed on the cell area. The overlay area may be positioned around the cell area. Overlay patterns, such as the lower pattern 40 and the upper pattern 60 corresponding to the unit cell patterns, may be formed on the overlay area.

The lower pattern 40 may have a first pitch P1. For example, the lower pattern 40 may include a plurality of first unit patterns that are periodically arranged and spaced apart from each other by the first pitch P1.

The lower pattern 40 is shown as an embossed pattern. However, embodiments of the present disclosure are not necessarily limited thereto. For example, in an embodiment the lower pattern 40 may be an engraved pattern. In an embodiment, the lower pattern 40 may be made of various materials to constitute a semiconductor device. In one example, the lower pattern 40 may include a conductive material such as metal, metal nitride, metal silicide, or metal silicide nitride. In another example, the lower pattern 40 may include an insulating material such as silicon oxide, silicon nitride, silicon oxynitride, etc. In another example, the lower pattern 40 may include a semiconductor material such as polysilicon.

In some embodiments, the lower pattern 40 may be formed on (e.g., formed directly thereon) the lower film 30. The lower film 30 may be formed on the substrate 100. The lower film 30 may be made of various materials such that the lower film 30 together with the lower pattern 40 may constitute a semiconductor device. In one example, the lower film 30 may include a conductive material such as metal, metal nitride, metal silicide, or metal silicide nitride. In another example, the lower film 30 may include an insulating material such as silicon oxide, silicon nitride, silicon oxynitride, etc. In another example, the lower film 30 may include a semiconductor material such as polysilicon. The lower film 30 is shown as a single film. However, embodiments of the present disclosure are not necessarily limited thereto, and the lower film 30 may include multiple films made of different materials. In some other embodiments, the lower film 30 may be omitted.

After forming the lower pattern 40, a process to check whether the above-mentioned first exposure process has been properly performed and whether the pitch and a CD (Critical Dimension) of the lower pattern 40 have been implemented to match those of a target product may be performed.

Thereafter, referring to FIG. 6, FIG. 8, and FIG. 14, the upper pattern 60 may be formed from the second pre-reticle RE2 using the second illumination system 80 in block S300 (FIG. 14). The upper pattern 60 may be formed by performing a second exposure process using the second illumination system 80.

For example, the upper film 50 may be formed on the substrate 100 and the lower pattern 40. The upper pattern 60 may be formed on (e.g., formed directly thereon) the upper film 50. For example, the lower pattern 40 and the upper pattern 60 may be positioned at different levels from each other. In an embodiment, the upper film 50 may be formed to be thicker than the lower pattern 40 so as to cover the lower pattern 40. Furthermore, an upper surface of the upper film 50 may be flat.

In some embodiments, the upper film 50 may include a light-transmissive film that transmits light therethrough to the lower pattern 40 to facilitate the overlay measurement. For example, in an embodiment the upper film may include oxide. In an embodiment, the upper film 50 may include silicon oxide or silicon nitride. However, embodiments of the present disclosure are not necessarily limited thereto. The upper film 50 is shown as a single film in FIG. 6. However, embodiments of the present disclosure are not necessarily limited thereto, and the upper film 50 may include multiple films made of different materials.

The upper pattern 60 may have a second pitch P2. For example, the upper pattern 60 may include a plurality of second unit patterns that are periodically arranged and spaced apart from each other by the second pitch P2.

In some embodiments, the upper pattern 60 may include a photoresist that is photosensitive. For example, in an embodiment a photoresist film may be applied on the upper film 50 in an application process such as a spin coating process, a dip coating process, or a spray coating process. The upper pattern 60 may be a photoresist pattern formed after an exposure process and a developing process have been performed on the photoresist film.

In some embodiments, the upper pattern 60 may include a photoresist for extreme ultraviolet (EUV) (e.g., about 13.5 nm), a photoresist for KrF excimer laser (e.g., about 248 nm), a photoresist for ArF excimer laser (e.g., about 193 nm), or a photoresist for F₂ excimer laser (e.g., about 157 nm). However, embodiments of the present disclosure are not necessarily limited thereto.

In some embodiments, the upper pattern 60 may include the photoresist for extreme ultraviolet (EUV). In an embodiment, the upper pattern 60 may be made of an organic photoresist containing an organic polymer such as polyhydroxystyrene. The organic photoresist may further contain a material with a high EUV absorption, for example, an organometallic material, an iodine-containing material, or a fluorine-containing material. In another example, the upper pattern 60 may be made of an inorganic photoresist containing an inorganic material such as tin oxide.

For example, in an embodiment the first illumination system 70 for forming the lower pattern 40 and the second illumination system 80 for forming the upper pattern 60 may be different from each other. In this embodiment, the second pitch P2 may be different from the first pitch P1.

After forming the upper pattern 60, a process to check whether the aforementioned second exposure process has been properly performed and whether the pitch and a CD (Critical Dimension) of the upper pattern 60 have been implemented to match those of the target product may be performed.

Accordingly, the overlay measurement stack OS including the lower pattern 40 and the upper pattern 60 may be formed.

In an embodiment, a process that optimizes (e.g., adjusts) a condition for measuring the overlay of the lower pattern 40 and the upper pattern 60 may be performed. For example, after the overlay measurement stack OS has been formed, a process of optimizing recipe information as setting information for measuring the overlay may be performed. This may be performed through the analysis software or applications executed by the computing system (20 in FIG. 1).

Afterwards, the overlay of the lower pattern 40 and the upper pattern 60 may be measured in block S400.

For example, in an embodiment the measuring of the overlay may be performed by ADI (After Development Inspection). In this embodiment, the measured overlay may include ADI data.

In an embodiment, a corrected reticle may then be formed based on the measured overlay in block S500 (FIG. 14). For example, a result of correcting components of average overlay values based on the measured overlay may be obtained, as will be described later, and the corrected reticle may be formed using the result.

After the corrected reticle has been formed, subsequent lots (e.g., based on approximately 25 wafers) may be inputted into the semiconductor manufacturing facility.

Referring to FIG. 9, for example, in an embodiment the shot area SA may have N rows Row1 to RowN and M columns Col1 to ColM. Hereinafter, an overlay measurement method according to some embodiments will be described based on N rows Row1 to RowN and M columns Col1 to ColM.

Overlay values (e.g., measured overlay error values) may be indicated as arrows in areas where the N rows Row1 to RowN and the M columns Col1 to ColM intersect each other, respectively. A size of the arrow may indicate a size of the overlay value (e.g., the measured overlay value error), and a direction of the arrow may indicate a direction of the overlay. However, the size and the direction of the arrow representing the overlay value are illustrative, and embodiments of the present disclosure are not necessarily limited to those shown in FIG. 9.

In an embodiment, averages of the respective overlay values of the M columns Col1 to Col1M may be calculated. In other words, first average overlay values corresponding to the columns in FIG. 9 may be calculated. In an embodiment, the first average overlay values may represent average overlay values in a slit direction (e.g., the first direction D1 in FIG. 3 and FIG. 4). In an embodiment, averages of the respective overlay values of the N rows Row1 to RowN may be calculated. In other words, second average overlay values correspond to the rows in FIG. 9 may be calculated. In an embodiment, the second average overlay values may represent average overlay values in the second direction D2 in FIG. 3 and FIG. 4.

FIG. 10 is a graph showing a result of correcting components in an x-axis direction of the first average overlay values as calculated from FIG. 9. The x-axis direction may be a row direction.

In FIG. 10, (a) represents a result of correcting the x-axis components of the first average overlay values according to some embodiments. In FIG. 10, (b) represents a result of correcting the x-axis components of the average overlay values of the actual cell pattern.

FIG. 11 is a graph showing a result of correcting components in a y-axis direction of the first average overlay values as calculated from FIG. 9. In an embodiment, the y-axis direction may be a column direction (e.g., the second direction D2 in FIG. 3 and FIG. 4).

In FIG. 11, (a) represents a result of correcting the y-axis components of the first average overlay values according to some embodiments. In FIG. 11, (b) represents a result of correcting the y-axis components of the average overlay values of the actual cell pattern.

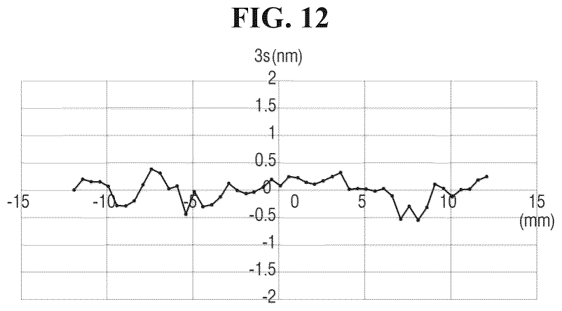

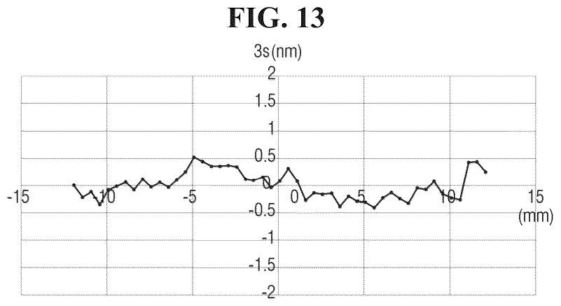

FIG. 12 and FIG. 13 are diagrams for illustrating an effect of a method for manufacturing a semiconductor device according to some embodiments. For economy of description, descriptions of contents that are the same as those as described above using FIGS. 1 to 11 and FIG. 14 may be omitted.

Referring to FIG. 13, it may be identified based on a comparison between the result of correcting the x-axis components of the first average overlay values in FIG. 10 and the result of correcting the x-axis components of the average overlay values of the actual cell pattern that a difference therebetween is close to 0. For example, it may be identified that the result of correcting the x-axis components of the first average overlay values extracted according to some embodiments is similar to the result of correcting the x-axis components of the average overlay values of the actual cell pattern.

Referring to FIG. 14, it may be identified based on a comparison between the result of correcting the y-axis components of the first average overlay values in FIG. 11 and the result of correcting the y-axis components of the average overlay values of the actual cell pattern that a difference therebetween is close to 0. For example, it may be identified that the result of correcting the y-axis components of the first average overlay values extracted according to some embodiments is similar to the result of correcting the y-axis components of the average overlay values of the actual cell pattern.

According to the overlay measurement method according to some embodiments, a 3s (3 times of a standard deviation) value of the overlay values may be reduced as shown in [Table 1] below.

TABLE 1

| | Before | After | | |
|---|---|---|---|---|
| | correction | correction | Improvement | Improvement |
| 3-sigma | (nm) | (nm) | amount (nm) | percentage (%) |
| X direction | 1.27 | 0.64 | 0.63 | 49.6% |
| Y direction | 1.58 | 0.75 | 0.83 | 52.5% |

For example, according to the overlay measurement method according to some embodiments, the 3s value of the x-direction overlay values may be reduced by about 49.6%, and the 3s value of the y-direction overlay values may be reduced by about 52.5%. For example, according to the overlay measurement method of some embodiments, a semiconductor chip may be formed by forming a reticle with a pre-corrected overlay using the pre-reticle for evaluation. Accordingly, misalignment of the patterns may be reduced, and the overlay measurement process may be further simplified.

Although embodiments of the present disclosure have been described with reference to the accompanying drawings, embodiments of the present disclosure are not necessarily limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the described embodiments are not restrictive.

What is claimed is:

1. A method for manufacturing a semiconductor device, the method comprising:
providing a first pre-reticle including a first overlay mark and a first on-cell pattern;
providing a second pre-reticle including a second overlay mark and a second on-cell pattern;
forming a first pattern from the first pre-reticle using a first illumination system;
forming a second pattern from the second pre-reticle using a second illumination system;
measuring an overlay error between the first pattern and the second pattern; and
forming a corrected reticle based on the measured overlay error.

2. The method of claim 1, wherein the first pattern and the second pattern are formed at different vertical levels from each other.

3. The method of claim 1, wherein a first pitch of the first pattern is different from a second pitch of the second pattern.

4. The method of claim 1, further comprising, after forming the first pattern and the second pattern, adjusting a condition for measuring the overlay error.

5. The method of claim 1, wherein measuring of the overlay error includes measuring the overlay using After Development Inspection.

6. The method of claim 1, further comprising, after measuring the overlay error,
obtaining a first average overlay value in a first direction; and
obtaining a second average overlay value in a second direction intersecting the first direction.

7. The method of claim 6, wherein the forming of the corrected reticle includes forming the corrected reticle using the obtained first average overlay value and the obtained second average overlay value.

8. The method of claim 1, wherein the second pattern includes photoresist,
wherein the first pattern includes a conductive material.

9. The method of claim 1, wherein the first illumination system uses a laser light source, and the second illumination system uses an EUV light source.

10. A method for manufacturing a semiconductor device, the method comprising:
providing a pre-reticle including an overlay mark and an on-cell pattern;
forming an overlay measurement stack from the pre-reticle, wherein the overlay measurement stack includes a lower pattern and an upper pattern;
measuring an overlay error between the lower pattern and the upper pattern; and
forming a corrected reticle based on the measured overlay error,
wherein the forming of the overlay measurement stack includes:
forming the lower pattern from a first pre-reticle using a first illumination system; and
forming the upper pattern on top of the lower pattern from a second pre-reticle using a second illumination system.

11. The method of claim 10, wherein the forming of the overlay measurement stack further includes forming a light-transmissive film between the lower pattern and the upper pattern.

12. The method of claim 10, further comprising, after forming the overlay measurement stack, adjusting a condition for measuring the overlay error.

13. The method of claim 10, further comprising, after measuring the overlay error,
obtaining a first average overlay value in a first direction; and
obtaining a second average overlay value in a second direction intersecting the first direction.

14. The method of claim 13, wherein the forming of the corrected reticle includes forming the corrected reticle using the obtained first average overlay value and the obtained second average overlay value.

15. The method of claim 10, wherein:
the upper pattern includes photoresist; and
the lower pattern includes polysilicon.

16. A method for manufacturing a semiconductor device, the method comprising:
providing a first pre-reticle including first overlay marks;
providing a second pre-reticle including second overlay marks;
forming an overlay measurement wafer from the first and second pre-reticles, wherein the overlay measurement wafer includes a lower pattern and an upper pattern;
measuring an overlay error between the lower pattern and the upper pattern; and
forming a corrected reticle based on the measured overlay error,
wherein the forming of the overlay measurement wafer includes:
forming the lower pattern from the first pre-reticle using a first illumination system of a first cell pattern;
forming a light-transmissive film on the lower pattern; and
forming an upper pattern on the light-transmissive film from the second pre-reticle using a second illumination system of a second cell pattern.

17. The method of claim 16, wherein the forming of the overlay measurement wafer includes:
forming the lower pattern by performing a first exposure process using the first illumination system; and
forming the upper pattern by performing a second exposure process using the second illumination system.

18. The method of claim 16, further comprising, after forming the overlay measurement wafer, adjusting a condition for measuring the overlay error.

19. The method of claim 16, wherein the light-transmissive film includes oxide.

20. The method of claim 16, further comprising, after measuring the overlay,
obtaining a first average overlay value in a first direction; and
obtaining a second average overlay value in a second direction intersecting the first direction,
wherein the forming of the corrected reticle includes forming the corrected reticle using the obtained first average overlay value and the obtained second average overlay value.
